(19) United States
(12) Patent Application Publication
(10) Pub. No.: US 2026/0052871 A1
(43) Pub. Date: Feb. 19, 2026

(54) DISPLAY DEVICE, METHOD OF MANUFACTURING DISPLAY DEVICE, AND ELECTRONIC DEVICE INCLUDING THE DISPLAY DEVICE

(71) Applicant: SAMSUNG DISPLAY CO., LTD., YONGIN-SI (KR)

(72) Inventor: YOUN-WOONG KANG, Yongin-si (KR)

(21) Appl. No.: 19/274,798

(22) Filed: Jul. 21, 2025

(30) Foreign Application Priority Data
Aug. 13, 2024 (KR) 10-2024-0107978

(51) Int. Cl. H10K 59/131; H10H 29/01; H10H 29/49; H10K 59/12

(52) U.S. Cl. CPC H10K 59/1315; H10H 29/012; H10H 29/49; H10K 59/1201

(57) ABSTRACT

A display device includes a base layer including a first sub-base layer with a base opening, a first barrier layer disposed on the first sub-base layer, a second barrier layer disposed on the first barrier layer, and a second sub-base layer disposed on the second barrier layer, a metal layer disposed between the first barrier layer and the second barrier layer with a portion of the metal layer exposed through the base opening, a base film disposed inside the base opening, a bump electrode including a first portion disposed inside the base film and a second portion that extends from the base film in a first direction, and a conductive pattern disposed on the bump electrode and the metal layer, wherein the conductive pattern is in contact with one side surface of the first sub-base layer defining the base opening.

### CROSS-REFERENCE TO RELATED APPLICATIONS

This patent application claims priority under 35 U.S.C. § 119 to Korean Patent Application No. 10-2024-0107978 filed on Aug. 13, 2024, in the Korean Intellectual Property Office, the disclosure of which is incorporated by reference in its entirety herein.

### 1. TECHNICAL FIELD

Embodiments of the present disclosure are directed to a display device, a method of manufacturing the display device, and an electronic device including the display device.

### 2. DISCUSSION OF RELATED ART

Display devices, including televisions, monitors, smart phones, and tablet personal computers (PCs), feature display panels for presenting images to users. Various types of display panels have been developed, including liquid crystal displays (LCDs), organic light-emitting display (OLEDs), electro wetting display panels, and electrophoretic display panels.

A bump electrode is a conductive structure that serves as an interconnect between a display driving circuit and electrical components within the display panel. The bump electrode may be connected to the display panel using a conductive pattern. A weak or unreliable connection between the conductive pattern and the bump electrode can lead to serious functional issues in the display panel, including unstable display performance, higher power consumption, degradation of the display panel and reduced image quality.

### SUMMARY

Embodiments of the present disclosure provide a display device including a conductive pattern and a bump electrode to increase electrical connection reliability, a method of manufacturing the display device and an electronic device including the display device. Such may reduce resistance, enhance signal transmission stability and contribute to a reduction in the non-display area of the display device.

According to an embodiment, a display device includes a base layer including a first sub-base layer with a base opening, a first barrier layer disposed on the first sub-base layer, a second barrier layer disposed on the first barrier layer, and a second sub-base layer disposed on the second barrier layer, a metal layer disposed between the first barrier layer and the second barrier layer with a portion exposed through the base opening, a base film disposed inside the base opening, a bump electrode including a first portion disposed inside the base film and a second portion that extends from the base film in a first direction, and a conductive pattern disposed on the bump electrode and the metal layer, wherein the conductive pattern is in contact with one side surface of the first sub-base layer defining the base opening.

The conductive pattern may be spaced apart from the base film in the first direction.

The conductive pattern may be a plurality of conductive patterns, and the plurality of conductive patterns may be spaced apart from each other in a second direction intersecting the first direction on a plane.

A groove may be defined in the second barrier layer and the second sub-base layer.

A portion of the conductive pattern may be disposed inside the groove.

The groove may have a semicircular shape in a cross section.

The second sub-base layer may include a first inner surface defining the groove and a second inner surface connected to the first inner surface.

The second sub-base layer may include a first inner surface defining the groove, a second inner surface connected to the first inner surface, and a third inner surface connected to the second inner surface.

The groove may be a plurality of grooves, and the plurality of grooves may be spaced apart from each other in a second direction intersecting the first direction.

The groove may be a plurality of grooves, the bump electrode may be a plurality of bump electrodes, and the plurality of grooves may be arranged alternately with the bump electrodes in a second direction intersecting the first direction.

The groove may be a plurality of grooves, and the plurality of grooves may not overlap the bump electrode.

The groove may be a plurality of grooves, and the plurality of grooves may include a first groove group and a second groove group spaced apart from each other in the first direction, and the second groove group may be closer to the base film than the first groove group.

According to an embodiment, a method of manufacturing a display device includes forming a preliminary base layer including a first preliminary layer and a second preliminary layer disposed on a lower surface of the first preliminary layer and a metal layer disposed between the first preliminary layer and the second preliminary layer, etching a portion of the first preliminary layer to form a first sub-base layer having a base opening, etching the second preliminary layer to form a second sub-base layer having a groove, providing a circuit board including a base film and a bump electrode disposed inside the base film, etching a portion of the base film so that a portion of the bump electrode is exposed, positioning the circuit board on the second sub-base layer so that the bump electrode and the metal layer exposed by the base opening overlap each other, and forming a conductive pattern in contact with one side surface of the first sub-base layer on the bump electrode, the metal layer, and the second sub-base layer.

The forming of the conductive pattern in contact with the one side surface of the first sub-base layer on the bump electrode, the metal layer, and the second sub-base layer may include depositing a conductive material to be in contact with the one side surface of the first sub-base layer defining the base opening, forming a preliminary conductive pattern by curing the conductive material, and forming a plurality of conductive patterns by irradiating the preliminary conductive pattern with a laser.

The depositing of the conductive material to be in contact with the one side surface of the first sub-base layer defining the base opening may include depositing the conductive material to be spaced apart from the base film.

The forming of the conductive pattern in contact with the one side surface of the first sub-base layer on the bump electrode, the metal layer, and the second sub-base layer may include moving a portion of the conductive material into the groove, forming a preliminary protrusion pattern by curing the conductive material, and forming a plurality of protrusion patterns by irradiating the preliminary protrusion pattern with the laser, and the plurality of protrusion patterns may be connected to the plurality of conductive patterns.

The forming of the second sub-base layer having the groove by etching the second preliminary layer may include etching a portion of the second preliminary layer not overlapping the metal layer.

The forming of the second sub-base layer having the groove by etching the second preliminary layer may include etching the second preliminary layer to form a plurality of grooves alternately arranged with a plurality of metal patterns of the metal layer on a plane.

The forming of the second sub-base layer having the groove by etching the second preliminary layer may include forming a first groove group including a plurality of grooves by etching the second preliminary layer, and forming a second groove group including a plurality of grooves by etching the second preliminary layer in an area farther from the first sub-base layer than the first groove group, and the first groove group and the second groove group may be spaced apart from each other in a first direction, and the plurality of grooves of the first groove group and the second groove group may include grooves spaced apart from each other in a second direction intersecting the first direction.

The forming of the second sub-base layer having the groove by etching the second preliminary layer may include forming the groove in a polygonal shape or a semicircular shape on a cross section.

According to an embodiment, an electronic device includes a display device and a control circuit. The display device includes a base layer having a first sub-base layer disposed on a second sub-base layer, the first sub-base layer having a base opening, a metal layer disposed between the first sub-base layer and the second sub-base layer, with a portion of the metal layer exposed through the base opening, a base film disposed inside the base opening, a conductive pattern disposed on the bump electrode and the metal layer, wherein the conductive pattern is in contact with one side surface of the first sub-base layer defining the base opening. The control circuit is configured to supply electrical signals to the bump electrode for operating the display device.

### BRIEF DESCRIPTION OF THE FIGURES

The above and other objects and features of the present disclosure will become apparent by describing in detail embodiments thereof with reference to the accompanying drawings.

FIG. 1 is a perspective view of an electronic device according to an embodiment of the present disclosure.

FIG. 2 is an exploded perspective view of the electronic device according to an embodiment of the present disclosure.

FIG. 3 is a cross-sectional view of a display device along line I-I′ of FIG. 2.

FIG. 4 is a schematic cross-sectional view of a display module according to an embodiment of the present disclosure.

FIG. 5 is a plan view of a display module according to an embodiment of the present disclosure.

FIG. 6 is a schematic perspective view illustrating a portion of the display device according to an embodiment of the present disclosure.

FIG. 7 is a schematic plan view of the display device according to an embodiment of the present disclosure.

FIG. 8 is a schematic cross-sectional view illustrating a portion of a non-display area of the display device.

FIGS. 9A to 9D are schematic perspective views illustrating the portion of the display device according to an embodiment of the present disclosure.

FIGS. 10A and 10B are schematic perspective views illustrating the portion of the display device according to an embodiment of the present disclosure.

FIGS. 11A to 11G are cross-sectional views illustrating some processes of a method for manufacturing a display device according to an embodiment of the present disclosure.

FIG. 12 illustrates an electronic device according to an embodiment of the present disclosure

### DETAILED DESCRIPTION

In the specification, when it is mentioned that a first component (or an area, a layer, a part, or the like) is connected or coupled to a second component, this means that the first component is directly disposed in/connected to/coupled to the second component or a third component is disposed therebetween.

The same reference numerals refer to the same components. The wording “and/or” includes all one or more combinations that may be defined by associated components.

Although the terms “first”, “second”, etc. may be used to describe various components, the components are not be limited by the terms. The terms are only used to distinguish one component from another component. For example, without departing from the right scope of the present disclosure, a first component may be referred to as a second component, and similarly, the second component may be also referred to as the first component. Singular expressions include plural expressions unless clearly otherwise indicated in the context.

Further, terms such as below, under, above, and on are used to describe the spatial relationships between components illustrated in the drawings. These relative terms are defined based on the orientation illustrated in the drawings.

It will be understood that terms such as “include”, “comprise” and “have” may indicate the presence of certain features, numbers, steps, operations, elements, or components as described in the specification, but do not preclude the possibility of additional features, numbers, steps, operations, elements, or components, either individually or in combination.

Hereinafter, embodiments of the present disclosure will be described with reference to the accompanying drawings.

The embodiments relate to a display device where electrical connection reliability between its conductive pattern and its bump electrodes has been enhanced, a method of manufacturing the display device and an electronic device including the display device. A structural configuration is introduced where a groove is formed in an upper layer of a base layer of a display panel of the display device, allowing the conductive patterns to be spaced apart from a base film of the display panel that supports the bump electrodes. This may prevent short circuits or interference between adjacent bump electrodes. Additionally, by extending along a side surface of a lower layer of the base layer, the conductive pattern may increase its contact area with a bump electrode, thereby reducing resistance and enhancing electrical reliability.

Beyond enhancing connectivity, these structural refinements may also contribute to reducing the non-display area of the display panel. By optimizing the arrangement of the conductive pattern and bump electrode, the display panel can be designed more compactly, potentially allowing for narrower bezels and a larger active display area without sacrificing performance.

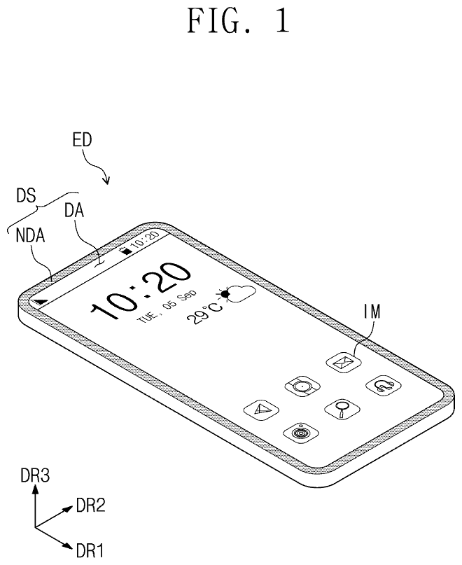

FIG. 1 is a perspective view of an electronic device ED according to an embodiment of the present disclosure.

Referring to FIG. 1, the electronic device ED according to an embodiment of the present disclosure may include a display surface DS defined by a first direction DR1 and a second direction DR2 intersecting the first direction DR1. The electronic device ED may provide an image IM to a user through the display surface DS.

The display surface DS may include a display area DA and a non-display area NDA around or adjacent to the display area DA. The display area DA may be an area on which the image IM is displayed, and the non-display area NDA may be an area on which the image IM is not displayed. The non-display area NDA may surround or be adjacent to the display area DA. However, the present disclosure is not limited thereto. For example, the shape of the display area DA and the shape of the non-display area NDA may vary from that depicted in FIG. 1.

Hereinafter, a direction substantially perpendicular to the plane defined by the first direction DR1 and the second direction DR2 is defined as a third direction DR3. The third direction DR3 may be a reference for distinguishing a front surface and a rear surface of each member. In the specification, the wording “on a plane” may be defined as a state in which the electronic device ED is viewed from the third direction DR3.

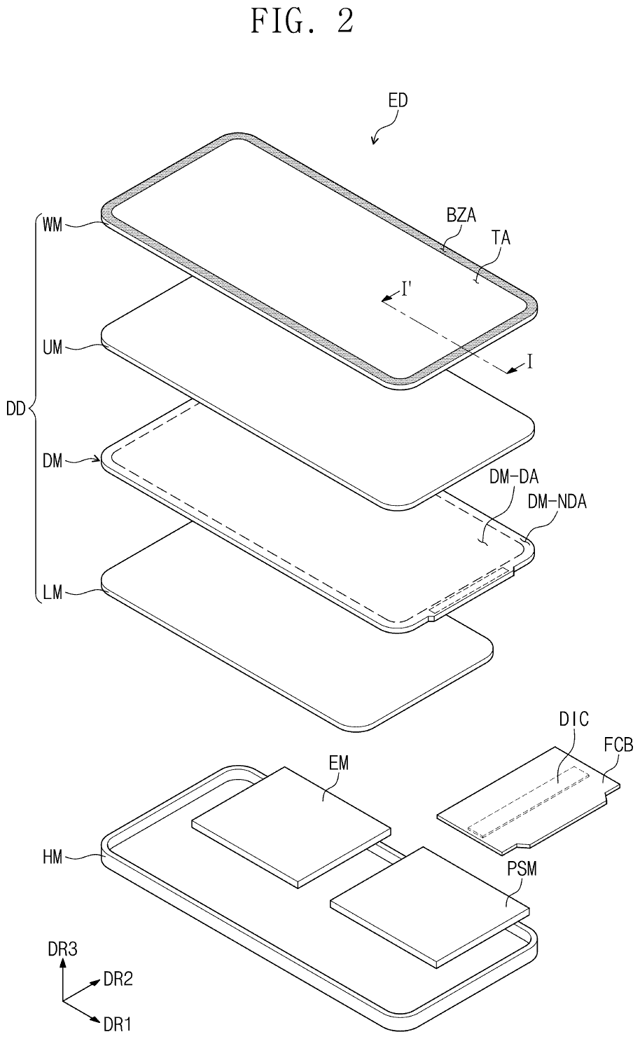

FIG. 2 is an exploded perspective view of the electronic device ED according to an embodiment of the present disclosure.

Referring to FIG. 2, the electronic device ED may include a display device DD, an electronic module EM (e.g., an electronic circuit), a power supply module PSM (e.g., a power supply circuit), and a housing HM. FIG. 2 briefly illustrates the electronic device ED.

The display device DD may generate the image IM and sense an external input. The display device DD may include a window WM, an upper member UM, a display module DM, a lower member LM, a circuit board (or a flexible circuit board) FCB, and a driving chip DIC. The upper member UM may include members disposed on the display module DM, and the lower member LM may include members disposed under the display module DM.

The window WM may provide a front surface of the electronic device ED. The window WM may include a transmissive area TA and a bezel area BZA. The display area DA and the non-display area NDA of the display surface DS illustrated in FIG. 1 may be defined by the transmissive area TA and the bezel area BZA. The transmissive area TA may be an area that allows light to pass through, enabling the perception of an image, and the bezel area BZA may be an area that covers a structure, member or component disposed under the window WM. The upper member UM may include a protective film or an optical film. The optical film may include a polarizer and a retarder to reduce reflection of external light.

The display module DM may include a display area DM-DA and a non-display area DM-NDA corresponding to the display area DA and the non-display area NDA illustrated in FIG. 1. In the specification, an expression “an area/part and an area/part correspond to each other” means that the area/part and the area/part overlap each other and is not limited to the same area.

The display module DM may have a substantially quadrangular shape. Here, the “substantially quadrangular shape” may include not only a quadrangular shape in the mathematical sense but also a shape similar to the quadrangular shape, which may be recognized as a quadrangular shape by the user. For example, the substantially quadrangular shape may include a quadrangular shape having rounded corner areas. Further, the substantially quadrangular shape is not strictly confined to a form where an edge of the display module DM is entirely linear since it may include a curved edge.

The lower member LM may include a protective film that protects a display panel DP, a support member that supports the display panel DP, a digitizer, and the like.

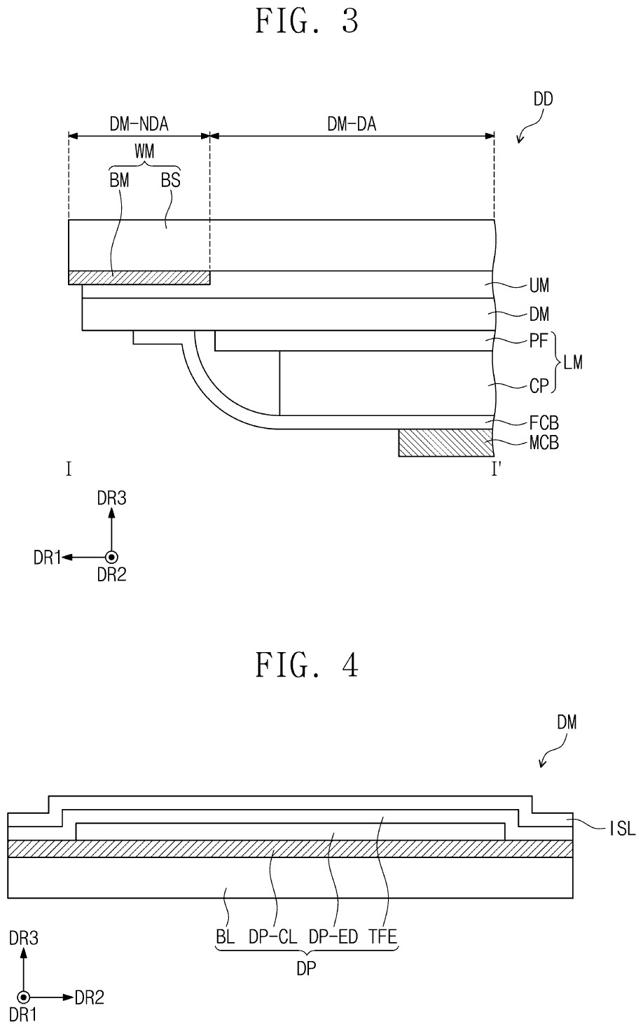

The circuit board FCB may be disposed under the display module DM. The circuit board FCB may be bonded to a rear surface of the display module DM. The circuit board FCB may electrically connect the display module DM and a main circuit board MCB (hereinafter, see FIG. 3). The circuit board FCB may include at least one insulating layer and at least one conductive layer. The conductive layer may include a plurality of signal lines.

The driving chip DIC may be mounted on the circuit board FCB. The driving chip DIC may include a driving circuit, for example, a data driving circuit, for driving pixels of the display panel DP. FIG. 2 illustrates a structure in which the driving chip DIC is mounted on the circuit board FCB, but the present disclosure is not limited thereto. For example, the driving chip DIC may be mounted on the display module DM or the main circuit board MCB.

The electronic module EM may include a control module, a wireless communication module, an image input module, a sound input module, a sound output module, a memory, an external interface module, and the like. The electronic module EM may include the main circuit board MCB, and the modules may be mounted on the main circuit board MCB or may be electrically connected to the main circuit board MCB through a flexible circuit board. The electronic module EM is electrically connected to the power supply module PSM.

Although not separately illustrated, the electronic device ED may further include an electro-optical module. The electro-optical module may be an electronic component that outputs or receives an optical signal. The electro-optical module may include a camera module and/or a proximity sensor. The camera module may capture an external image through a partial area of the display panel DP.

The housing HM illustrated in FIG. 2 is coupled to the display device DD, particularly, the window WM, to accommodate the other modules. While FIG. 2 illustrates that the housing HM has an integral shape, the present disclosure is not limited thereto. The housing HM may include a plurality of portions (e.g., a side edge portion and a bottom portion) coupled to each other.

FIG. 3 is a cross-sectional view of the display device DD along line I-I′ of FIG. 2.

Referring to FIG. 3, the window WM may include a base substrate BS and a bezel pattern BM disposed on a lower surface of the base substrate BS. The base substrate BS may include a synthetic resin film or a glass substrate. The base substrate BS may have a multi-layer structure. The base substrate BS may include a thin film glass substrate, a protective film disposed on the thin film glass substrate, and an adhesive layer that couples the thin film glass substrate and the protective film.

The bezel pattern BM, which is a colored light shielding film, may be formed by, for example, a coating method. The bezel pattern BM may include a base material and a dye or a pigment mixed with the base material. The bezel pattern BM may overlap the non-display area NDA illustrated in FIG. 1 and the bezel area BZA illustrated in FIG. 2. The bezel pattern BM may be disposed on the lower surface of the base substrate BS. When the base substrate BS has a multi-layer structure, the bezel pattern BM may be disposed between interfaces defined by a plurality of layers. For example, the bezel pattern BM may be disposed between the thin film glass substrate and the protective film. The window WM may further include at least one of a hard coating layer, a fingerprint preventing layer, and a reflection preventing layer on an upper surface of the base substrate BS.

The upper member UM may include an upper film. The upper film may include a synthetic resin film. The synthetic resin film may include polyimide, polycarbonate, polyamide, triacetylcellulose, polymethylmethacrylate, or polyethylene terephthalate. The upper film may absorb an external impact applied to a front surface of the display device DD (see FIG. 1). The upper member UM may overlap the bezel area BZA (see FIG. 2) and the transmissive area TA (see FIG. 2). The upper member UM may overlap only a portion of the bezel area BZA, leaving a portion of the bezel pattern BM exposed.

An adhesive layer that couples the upper member UM and the window WM may be further included between the upper member UM and the window WM. The adhesive layer may be a pressure sensitive adhesive (PSA) film or an optically clear adhesive (OCA) member.

The display module DM may be disposed under the upper member UM. The display module DM may overlap the bezel area BZA and the transmissive area TA. The display module DM may completely overlap the upper member UM in the bezel area BZA. A side surface of the display module DM may be aligned with the side surface of the upper member UM, and an edge of the display module DM may be aligned with an edge of the upper member UM on a plane.

The lower member LM may include a lower film PF and a cover panel CP. The lower film PF may be smaller in size compared to the display module DM. For example, the lower film PF may overlap only the display area DM-DA of the display module DM. The lower film PF may have a size that substantially corresponds to that of the display module DM.

The cover panel CP may be disposed under the lower film PF. The cover panel CP may increase resistance to compressive forces exerted by external pressure. Thus, the cover panel CP may serve to prevent deformation of the display module DM. The cover panel CP may include a flexible plastic material such as polyimide or polyethylene terephthalate. Further, the cover panel CP may be a colored film having a low light transmittance. The cover panel CP may absorb light input from the outside. For example, the cover panel CP may be a black synthetic resin film. When the display device DD is viewed from an upper side of the window WM, components arranged under the cover panel CP may not be visually recognized by the user.

A support plate may be further disposed under the cover panel CP. The support plate may include a metal material having high strength. The support plate may also include a reinforced fiber composite. The support plate may include a reinforced fiber disposed inside a matrix part. The reinforced fiber may be a carbon fiber or a glass fiber. The matrix part may include a polymer resin. The matrix part may include a thermoplastic resin. For example, the matrix part may include a polyamide-based resin or a polypropylene-based resin. For example, the reinforced fiber composite may be carbon fiber reinforced plastic (CFRP) or glass fiber reinforced plastic (GFRP).

The main circuit board MCB may be disposed on a lower surface of the circuit board FCB. The circuit board FCB may include an insulating film and conductive wiring lines mounted on the insulating film. The main circuit board MCB may include signal lines and electronic elements, which are not illustrated. The electronic elements may be connected to the signal lines and may be electrically connected to the display module DM. The electronic elements may generate various electrical signals, for example, signals for generating an image or signals for sensing an external input, or processing sensed signals. While, one main circuit board MCB may be provided or three or more main circuit boards MCB may be provided to correspond to the electrical signals to be generated and processed, the present disclosure is not limited to this embodiment.

FIG. 4 is a schematic cross-sectional view of the display module DM according to an embodiment of the present disclosure. In the description of FIG. 4, references are made to FIGS. 1 to 3, and explanations of elements with the same reference numerals will be omitted.

Referring to FIG. 4, the display module DM may include the display panel DP and an input sensing layer ISL. The display panel DP may include a base layer BL, a circuit layer DP-CL, a display element layer DP-ED, and an encapsulation layer TFE.

The circuit layer DP-CL may be disposed on an upper surface of the base layer BL. The base layer BL may be a flexible substrate that may be bent, folded, or rolled. The base layer BL may be a glass substrate, a metal substrate or a polymer substrate. However, embodiment of the present disclosure are not limited thereto. For example, the base layer BL may be an inorganic layer, an organic layer, or a composite material layer. The base layer BL may have substantially the same shape as the display panel DP.

The base layer BL may have a multi-layer structure. For example, the base layer BL may include a first synthetic resin layer, a second synthetic resin layer, and an inorganic layer disposed therebetween. Each of the first synthetic resin layer and the second synthetic resin layer may include a polyimide-based resin, but the present disclosure is not limited thereto.

The circuit layer DP-CL may be disposed on the base layer BL. The circuit layer DP-CL may include a plurality of insulating layers, a plurality of semiconductor patterns, a plurality of conductive patterns, and the signal lines. The circuit layer DP-CL may include a driving circuit of a pixel. Hereinafter, unless otherwise specified, when component “A” and component “B” are arranged on the same layer, it may be interpreted that component “A” and component “B” are formed by the same process and thus include the same material or have the same laminated structure. The conductive patterns or the semiconductor patterns arranged on the same layer may be interpreted as described above.

The display element layer DP-ED may be disposed on the circuit layer DP-CL. The display element layer DP-ED may include a light emitting element. For example, the light emitting element may include an organic light emitting material, an inorganic light emitting material, an organic-inorganic light emitting material, a quantum dot, a quantum rod, a micro-light emitting diode (LED), or a nano-LED.

The encapsulation layer TFE may be disposed on the display element layer DP-ED. The encapsulation layer TFE may protect the display element layer DP-ED, i.e., the light emitting element, from foreign substances such as moisture, oxygen, and dust particles. The encapsulation layer TFE may include at least one inorganic encapsulation layer. The encapsulation layer TFE may include a laminated structure of a first inorganic encapsulation layer, an organic encapsulation layer, and a second inorganic encapsulation layer.

The input sensing layer ISL may be directly disposed on the display panel DP. The input sensing layer ISL may sense an input of the user using, for example, an electromagnetic induction method or a capacitance method. The display panel DP and the input sensing layer ISL may be formed through a continuous process. Here, the fact that “the input sensing layer ISL is directly disposed on the display panel DP” may mean that a third component is not disposed between the input sensing layer ISL and the display panel DP. For example, a separate adhesive layer may not be disposed between the input sensing layer ISL and the display panel DP.

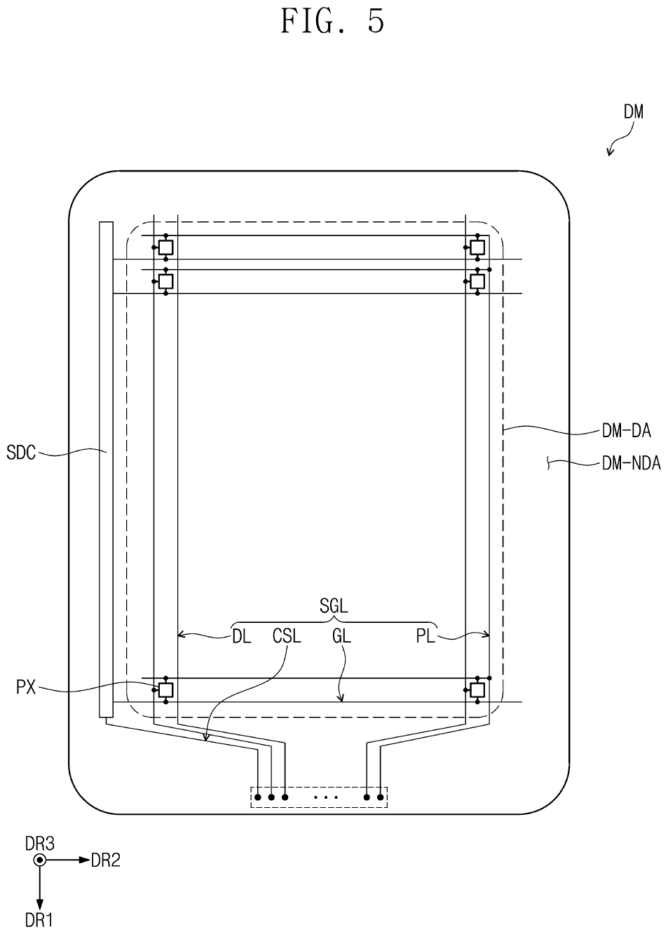

FIG. 5 is a plan view of the display module DM according to an embodiment of the present disclosure. In the description of FIG. 5, references are made to FIGS. 1 to 4, and explanations of elements with the same reference numerals will be omitted.

As illustrated in FIG. 5, the display module DM may include a scan driving circuit SDC, a plurality of signal lines SGL, and a plurality of pixels PX. The plurality of pixels PX are arranged in the display area DM-DA. Each of the pixels PX includes a light emitting element and a pixel driving circuit connected thereto. The scan driving circuit SDC, the plurality of signal lines SGL, and the pixel driving circuit may be included in the circuit layer DP-CL illustrated in FIG. 4.

The scan driving circuit SDC may include a gate driving circuit. The gate driving circuit may generate a plurality of scan signals and sequentially output the plurality of scan signals to a plurality of scan lines GL (or gate lines). The scan driving circuit SDC may further include a light emitting driving circuit that is distinguished from the gate driving circuit. The light emitting driving circuit may output scan signals to another group of scan lines. The scan driving circuit SDC may include a plurality of thin film transistors formed through the same process as the pixel driving circuit, for example, through a low temperature polycrystalline silicon (LTPS) process and/or a low temperature polycrystalline oxide (LTPO) process.

The plurality of signal lines SGL may include the scan lines GL, data lines DL, a power line PL, and a control signal line CSL. Distal ends of the plurality of signal lines SGL may be aligned with one side of the non-display area DM-NDA. The plurality of signal lines SGL may have an integral shape but may include a plurality of parts arranged on different layers. The plurality of signal lines SGL may be electrically connected to the main circuit board MCB (see FIG. 3).

Each of the scan lines GL may be connected to a corresponding pixel PX among the plurality of pixels PX. The scan lines GL may overlap the display area DM-DA and the non-display area DM-NDA.

Each of the data lines DL may be connected to a corresponding pixel PX among the plurality of pixels PX. The data lines DL may provide data signals to the pixels PX. The data lines DL may overlap the display area DM-DA and the non-display area DM-NDA. Different parts of the data lines, may be electrically connected through a contact hole that passes through the insulating layer. For example, the data lines DL may include a portion disposed in the display area DM-DA and another portion disposed in the non-display area DM-NDA, with the latter being disposed on a different layer than the portion disposed in the display area DM-DA. The portion disposed in the display area DM-DA and the portion disposed in the non-display area DM-NDA may include different materials and may have different laminated structures.

A plurality of power lines PL may be provided. The power lines PL may be connected to the plurality of pixels PX. For example, the power lines PL may include a first power line that receives a first power voltage and a second power line that receives a second power voltage having a higher level than that of the first power voltage. The first power voltage may be provided to the pixels PX through the first power line, and the second power voltage may be provided to the pixels PX through the second power line. The power line PL may overlap the display area DM-DA and the non-display area DM-NDA.

The control signal line CSL may provide control signals to the scan driving circuit SDC. Although one control signal line CSL is illustratively illustrated in FIG. 5, a plurality of control signal lines CSL may be provided. The control signal line CSL may overlap the non-display area DM-NDA.

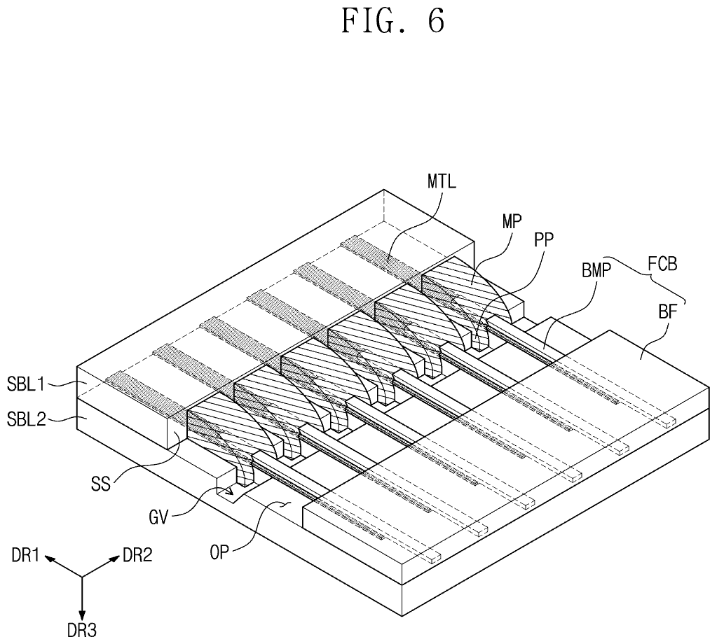

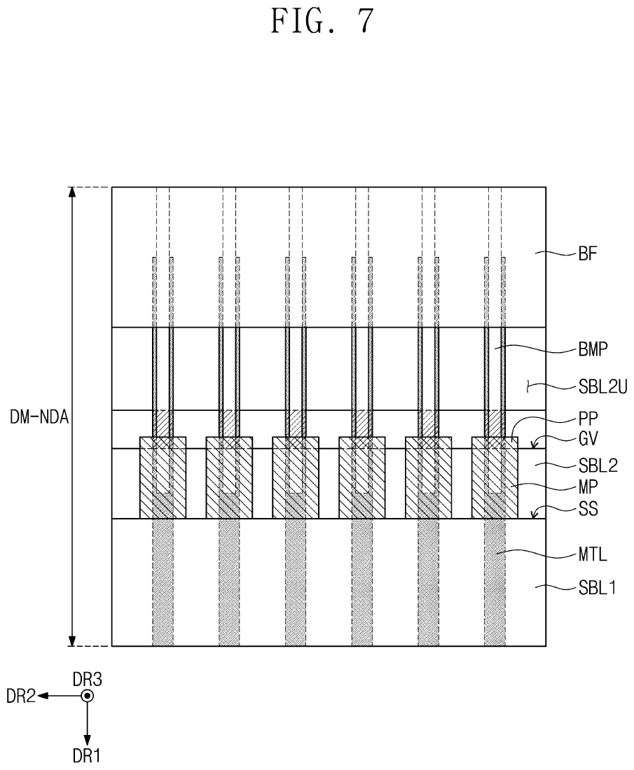

FIG. 6 is a schematic perspective view illustrating a portion of the display device DD according to an embodiment of the present disclosure. FIG. 7 is a schematic plan view of the display device DD according to an embodiment of the present disclosure. In description of FIGS. 6 and 7, references are made to FIGS. 1 to 5, and explanations of the same reference numerals will be omitted.

Referring to FIGS. 6 and 7, the display panel DP may include a base layer BL. In an embodiment, the base layer BL includes a first sub-base layer SBL1, a second sub-base layer SBL2, and a metal layer MTL. The circuit board FCB may include a bump electrode BMP and a base film BF.

In an embodiment, a base opening OP is defined in the first sub-base layer SBL1. The first sub-base layer SBL1 may include one side surface SS that defines the base opening OP and another side surface facing the one side surface SS. In an embodiment, the one side surface SS of the first sub-base layer SBL1 is adjacent to a conductive pattern MP, and the other side surface of the first sub-base layer SBL1 is adjacent to the base film BF. In an embodiment, a groove GV or a recess is defined in the second sub-base layer SBL2. For example, a portion of the second sub-base layer SBL2 may be removed to form the groove GV.

The circuit board FCB may be disposed inside the base opening OP of the first sub-base layer SBL1. In an embodiment, the bump electrode BMP of the circuit board FCB is electrically connected to the metal layer MTL by the conductive pattern MP, which will be described below.

FIGS. 6 and 7 illustrate that the base film BF is aligned with the second sub-base layer SBL2 in a cross section, but the base film BF need not be aligned with the second sub-base layer SBL2 on a cross section as long as the driving chip DIC is mounted on the base film BF to transmit an electrical signal to the display panel DP.

A portion of the bump electrode BMP may be disposed inside the base film BF, while the remaining portion may extend from the base film BF in the first direction DR1. For example, the bump electrode BMP may be disposed on the second sub-base layer SBL2. A distal end of the portion of the bump electrode BMP that extends may be spaced apart from the one side surface SS of the first sub-base layer SBL1 that defines the base opening OP. A plurality of bump electrodes BMP may be provided. While FIGS. 6 and 7 illustrate six bump electrodes BMP, the embodiments are not limited thereto. For example, five or less bump electrodes BMP or seven or more bump electrodes BMP may be provided in the display device DD.

In an embodiment, the metal layer MTL is disposed between the first sub-base layer SBL1 and the second sub-base layer SBL2. The metal layer MTL may extend in a direction parallel to the first direction DR1 on a plane. A portion of the metal layer MTL may be exposed by the base opening OP. The bump electrode BMP may be disposed on the portion of the metal layer MTL exposed by the base opening OP. The metal layer MTL and the bump electrode BMP may be electrically connected to each other by the conductive pattern MP.

The metal layer MTL may be provided as a plurality of metal layers MTL. FIGS. 6 and 7 illustrate six metal layers MTL, but the embodiments are not limited thereto. For example, five or less metal layers MTL or seven or more metal layers MTL may be provided in the display device DD. The number of the plurality of metal layers MTL may be provided to correspond to the number of the plurality of bump electrodes BMP.

In an embodiment, the groove GV is formed to be spaced apart from the one side surface SS of the first sub-base layer SBL1 in a direction opposite to the first direction DR1. The groove GV may be formed by removing an upper surface of the second sub-base layer SBL2. The groove GV may be provided as a plurality of grooves GV. The plurality of grooves GV may be arranged to be spaced apart from each other in the second direction DR2 intersecting the first direction DR1. In an embodiment, the plurality of grooves GV do not overlap the bump electrode BMP on a plane. The plurality of grooves GV may not be defined in a portion overlapping the bump electrode BMP and the metal layer MTL. The plurality of grooves GV may be arranged alternately with the bump electrode BMP in the second direction DR2 intersecting the first direction DR1. For example, the grooves GV, which are spaced apart from one another, may be arranged alternately with the bump electrodes BMP along the second direction DR2.

In an embodiment, the conductive pattern MP is disposed on the second sub-base layer SBL2, the metal layer MTL, and the bump electrode BMP. For example, the conductive pattern MP may be formed to cover the metal layer MTL and the bump electrode BMP. The conductive pattern MP may cover the metal layer MTL and the bump electrode BMP to electrically connect the metal layer MTL and the bump electrode BMP. The conductive pattern MP may be provided as a plurality of conductive patterns MP, and the plurality of conductive patterns MP may be spaced apart from each other in the second direction DR2 intersecting the first direction DR1 on a plane. The plurality of conductive patterns MP may be spaced apart from each other so they are not in contact with each other.

A portion of the conductive pattern MP may be disposed inside the groove GV defined by the second sub-base layer SBL2. The conductive pattern MP disposed inside the groove GV may be defined as a protrusion pattern PP. For example, a portion of the conductive pattern MP may protrude into the groove GV. The protrusion pattern PP may be formed by curing a conductive material that forms the conductive pattern MP, after it flows into the groove GV. That is, the protrusion pattern PP may include the same material as the conductive pattern MP and may be formed through the same process. The protrusion pattern PP may either remain connected to the corresponding conductive pattern MP or become disconnected from it as it flows into the groove GV.

FIG. 6 illustrates that a portion (or the protrusion pattern PP) of the conductive pattern MP is disposed in the groove GV, but the protrusion pattern PP may not be disposed inside the groove GV when no conductive material flows into the groove GV during a process of forming the conductive pattern MP.

The conductive pattern MP may be spaced apart from the base film BF on a plane. When a large amount of conductive material is deposited during the process of forming the conductive pattern MP, the conductive material may flow into the groove GV defined by the second sub-base layer SBL2. That is, even when a large amount of conductive material is deposited, the cured conductive pattern MP may remain spaced apart from the base film BF as the conductive material settles into the groove GV. The protrusion pattern PP may be spaced apart from the base film BF by a distance between the base film BF and a distal end adjacent to the base film BF among distal ends of the second sub-base layer SBL2 defining the groove GV.

When the groove GV is not defined in the second sub-base layer SBL2, the conductive pattern MP may be in contact with the base film BF. The conductive pattern MP in contact with the base film BF may be also disposed inside the base film BF. In this case, the conductive pattern MP may be disposed between the plurality of bump electrodes BMP spaced apart from each other to electrically connect the plurality of bump electrodes BMP. A signal of each of the plurality of bump electrodes BMP may not be independently transmitted to the display panel DP (see FIG. 4).

According to the present disclosure, since the groove GV is defined in the second sub-base layer SBL2, the conductive pattern MP may be formed to be spaced apart from the base film BF. When the conductive pattern MP is spaced apart from the base film BF, the plurality of conductive patterns MP may prevent the plurality of bump electrodes BMP from being electrically connected to each other. The signal of each of the plurality of bump electrodes BMP may be independently transmitted to the display panel DP (see FIG. 4). This spacing prevents unintended electrical connections between the plurality of bump electrodes BMP, ensuring that each bump electrode BMP remains electrically isolated. As a result, signals from each bump electrode BMP can be independently transmitted to the display panel DP, enhancing signal integrity and reducing the risk of signal interference or short circuits.

In an embodiment, the conductive pattern MP is in contact with the one side surface SS of the first sub-base layer SBL1 defining the base opening OP. The conductive pattern MP may extend in the direction opposite to the first direction DR1 from the one side surface SS of the first sub-base layer SBL1. As the conductive pattern MP extends, an area in which the bump electrode BMP and the conductive pattern MP overlap each other may increase. When a contact area between the conductive pattern MP and the bump electrode BMP increases, a resistance therebetween may be reduced. Electrical connection reliability between the conductive pattern MP and the bump electrode BMP may be reduced due to the reduction in the resistance between the conductive pattern MP and the bump electrode BMP.

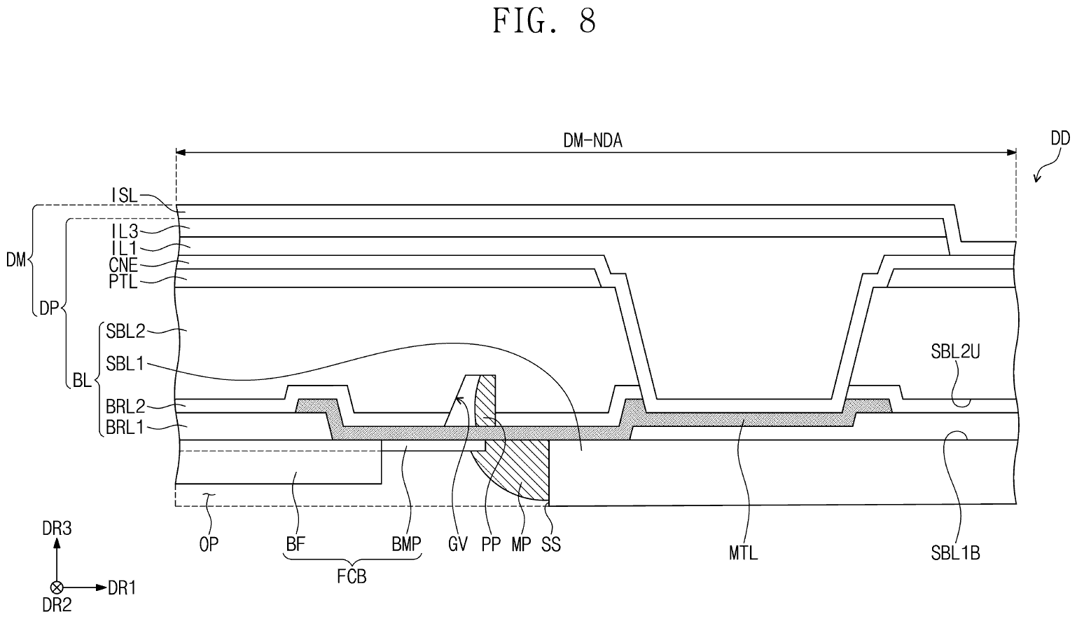

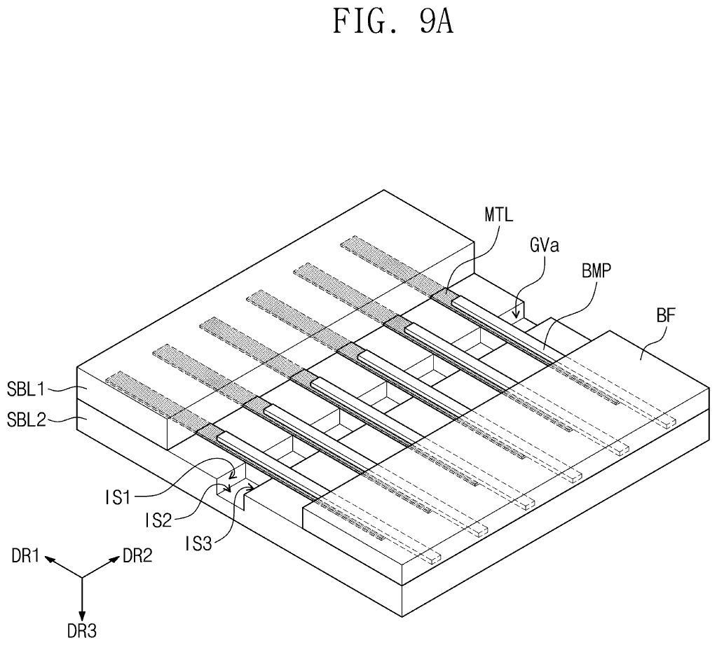

FIG. 8 is a schematic cross-sectional view illustrating a portion of the non-display area DM-NDA of the display device DD. In the description of FIG. 8, references are made to FIGS. 1 to 7, and the explanations of the same reference numerals will be omitted.

Referring to FIG. 8, the base layer BL may further include a first barrier layer BRL1 disposed on the first sub-base layer SBL1 and a second barrier layer BRL2 disposed on the first barrier layer BRL1. The first sub-base layer SBL1 and the second sub-base layer SBL2 may include an organic material or a synthetic resin material, for example, polyimide.

The first sub-base layer SBL1, which defines the base opening OP in a cross section, may extend in the direction parallel to the first direction DR1. In an embodiment, the first sub-base layer SBL1 is disposed closer to the circuit board FCB than what was done in the past. The first barrier layer BRL1 may be disposed on the first sub-base layer SBL1. For example, a portion of the first barrier layer BRL1 may be disposed on a lower surface SBL1B of the first sub-base layer SBL1.

The metal layer MTL may be disposed between the first barrier layer BRL1 and the second barrier layer BRL2. The base opening OP may be defined in the first sub-base layer SBL1, and at least a portion of the metal layer MTL may be exposed by the base opening OP. A portion of the metal layer MTL may overlap the circuit board FCB. The metal layer MTL may overlap the bump electrode BMP and may be electrically connected to the bump electrode BMP by the conductive pattern MP.

The metal layer MTL may be provided as a plurality of metal layers MTL. For example, the metal layer MTL may be patterned so that the plurality of metal layers MTL are provided in the non-display area DM-NDA in a pattern shape. The plurality of metal layers MTL may be electrically connected to the data line DL illustrated in FIG. 5 through a connection electrode CNE disposed on the plurality of metal layers MTL. The plurality of metal layers MTL may overlap the non-display area DM-NDA.

The second barrier layer BRL2 may be disposed on the first barrier layer BRL1. The second barrier layer BRL2 may be disposed on the first barrier layer BRL1 and the metal layer MTL. For example, the second barrier layer BRL2 may include a silicon nitride, a silicon oxy nitride, or a silicon oxide.

The second sub-base layer SBL2 may be disposed on the second barrier layer BRL2. The groove GV described in FIGS. 6 and 7 may be defined in the second barrier layer BRL2 and the second sub-base layer SBL2. The groove GV may form a through-hole within the second barrier layer BRL2.

The display device DD according to the present disclosure may further include a protective layer PTL disposed on the base layer BL. For example, the protective layer PTL may be disposed in direct contact with the second sub-base layer SBL2. In an embodiment, a thickness (e.g., in direction DR3) of the protective layer PTL is smaller than a thickness of the second sub-base layer SBL2. The protective layer PTL may include at least one inorganic layer. For example, the inorganic layer may include a silicon nitride, a silicon oxy nitride, or a silicon oxide.

The display device DD according to the present disclosure may further include the connection electrode CNE disposed on the base layer BL. The connection electrode CNE may be electrically connected to the metal layer MTL through a contact hole.

The circuit board FCB may include the base film BF and the bump electrode BMP disposed in the base film BF. The base film BF and the bump electrode BMP may be integrally formed. For example, a single layer may be used to form the base film BF and the bump electrode BMP. In this case, the base film BF may include a synthetic resin material, for example, polyimide.

The conductive pattern MP may electrically connect the metal layer MTL and the bump electrode BMP. The bump electrode BMP may be electrically connected to the connection electrode CNE through the metal layer MTL. The bump electrode BMP may be provided as a plurality of bump electrodes BMP, the conductive pattern MP may be provided as a plurality of conductive patterns MP, and the plurality of conductive patterns MP may be provided to correspond to the number of the plurality of bump electrodes BMP.

Each of the conductive patterns MP may be a pattern obtained by curing a metal ink. The conductive pattern MP may include a solder paste. The conductive pattern MP may be formed from a metal ink containing silver (Ag), copper (Cu) or another metal conductor. The conductive pattern MP may be formed by curing and then patterning the metal ink. The patterning may include irradiation of a laser. The conductive pattern MP may be formed at a low temperature, and the metal layer MTL and the bump electrode BMP may be electrically connected and bonded to each other at the same time without a high-temperature pressing process.

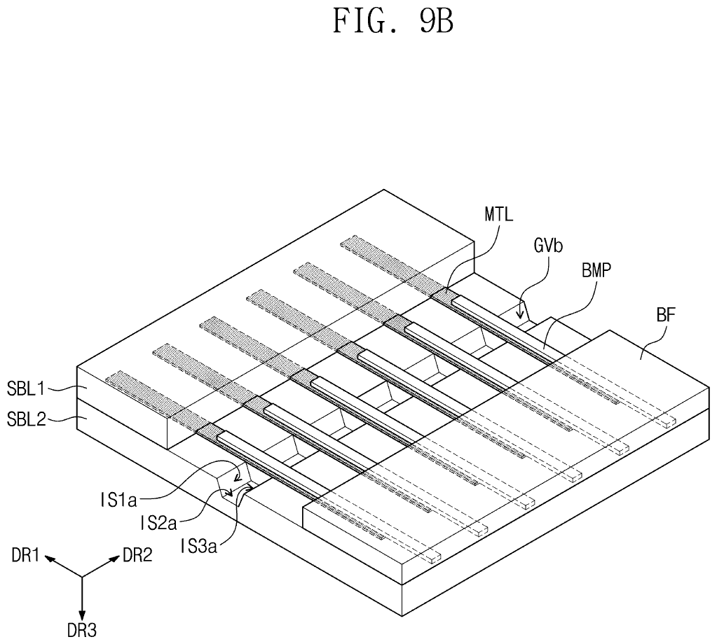

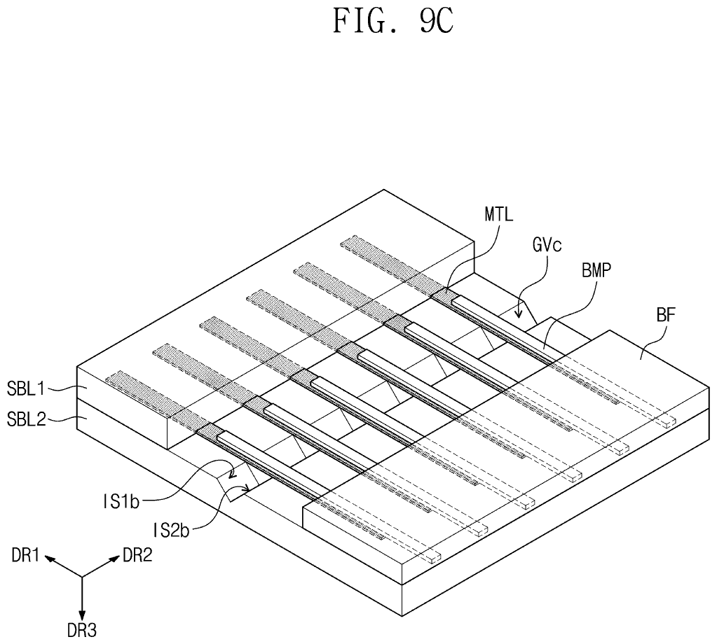

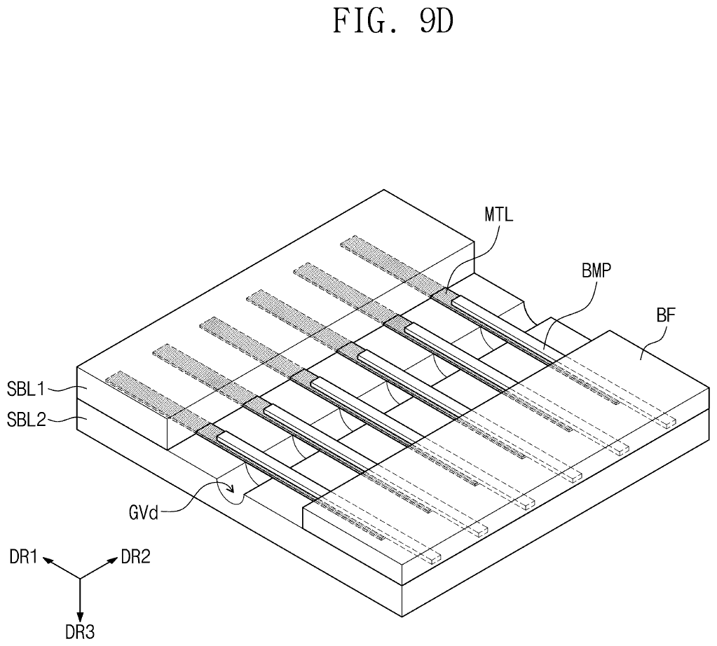

FIGS. 9A to 9D are schematic perspective views illustrating the portion of the display device DD according to an embodiment of the present disclosure. In FIGS. 9A to 9D, for convenience of description, the conductive pattern MP of the display device DD corresponding to FIG. 6 is omitted. In the description of FIGS. 9A to 9D, reference is made to FIGS. 1 to 8, and explanations of the same reference numerals will be omitted.

Referring to FIG. 9A, the second sub-base layer SBL2 may include a first inner surface IS1 that defines a groove GVa, a second inner surface IS2 that is connected to the first inner surface IS1, and a third inner surface IS3 that is connected to the second inner surface IS2. The first inner surface IS1 and the second inner surface IS2 may form a predetermined angle. An angle formed between the first inner surface IS1 and the second inner surface IS2 may be an acute angle, a right angle, or an obtuse angle. For example, the angle formed between the first inner surface IS1 and the second inner surface IS2 may be a right angle. The second inner surface IS2 and the third inner surface IS3 may form a predetermined angle. An angle formed between the second inner surface IS2 and the third inner surface IS3 may be an acute angle, a right angle, or an obtuse angle. For example, the angle formed between the second inner surface IS2 and the third inner surface IS3 may be a right angle. That is, the groove GVa may have a rectangular shape in a cross section.

Referring to FIG. 9B, the second sub-base layer SBL2 may include a first inner surface IS1a that defines a groove GVb, a second inner surface IS2a that is connected to the first inner surface IS1a, and a third inner surface IS3a that is connected to the second inner surface IS2a. The first inner surface IS1a and the second inner surface IS2a may form a predetermined angle. An angle formed between the first inner surface IS1a and the second inner surface IS2a may be an acute angle, a right angle, or an obtuse angle. For example, the angle formed between the first inner surface IS1a and the second inner surface IS2a may be an obtuse angle. The second inner surface IS2a and the third inner surface IS3a may form a predetermined angle. An angle formed between the second inner surface IS2a and the third inner surface IS3a may be an acute angle, a right angle, or an obtuse angle. For example, the angle formed between the second inner surface IS2a and the third inner surface IS3a may be an obtuse angle. That is, the groove GVb may have a trapezoidal shape in a cross section.

FIGS. 9A and 9B illustrate the groove GVa or GVb having a rectangular shape or a trapezoidal shape, but the present disclosure is not limited thereto. For example, the angle formed between the first inner surface and the second inner surface defining the groove GV of FIG. 6 may be a right angle, and the angle formed between the second inner surface and the third inner surface may be an obtuse angle. The groove GV may have various polygonal shapes in a cross section.

Referring to FIG. 9C, the second sub-base layer SBL2 may include a first inner surface IS1b that defines a groove GVc and a second inner surface IS2b connected to the first inner surface IS1b. The first inner surface IS1b and the second inner surface IS2b may form a predetermined angle. An angle formed between the first inner surface IS1b and the second inner surface IS2b may be an acute angle, a right angle, or an obtuse angle. For example, the angle formed between the first inner surface IS1b and the second inner surface IS2b may be an acute angle. That is, the groove GVc may have a triangular shape in a cross section.

Referring to FIG. 9D, the groove GV may have a semicircular shape in a cross section. An inner surface of the second sub-base layer SBL2 defining the groove GV may have a semicircular shape without forming an angle. For example, the groove GV may have a concave shape. As illustrated in FIGS. 9A to 9D, the groove GVa, GVb, GVc, or GVd may have various shapes. The shape of the groove GVa, GVb, GVc, or GVd is not limited to any one shape as long as the conductive material is allowed to flow without contacting the base film BF in a process of depositing the conductive material constituting the conductive pattern MP.

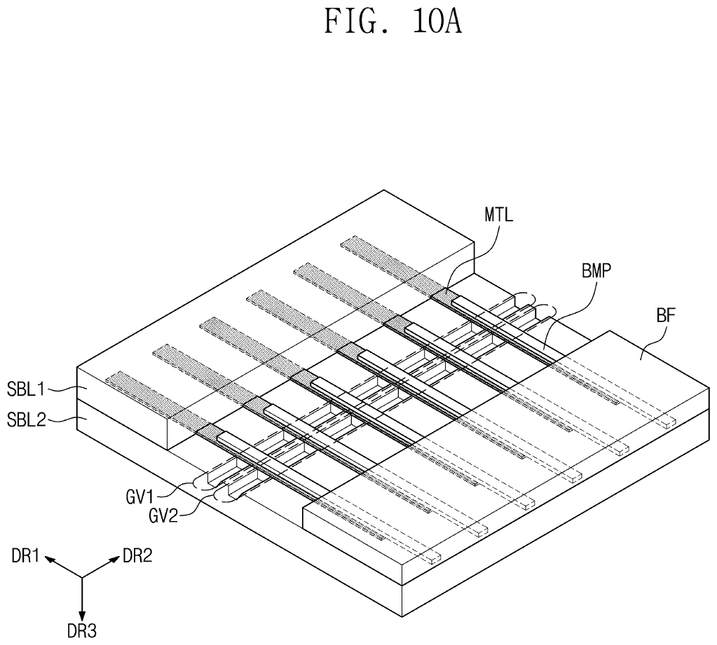

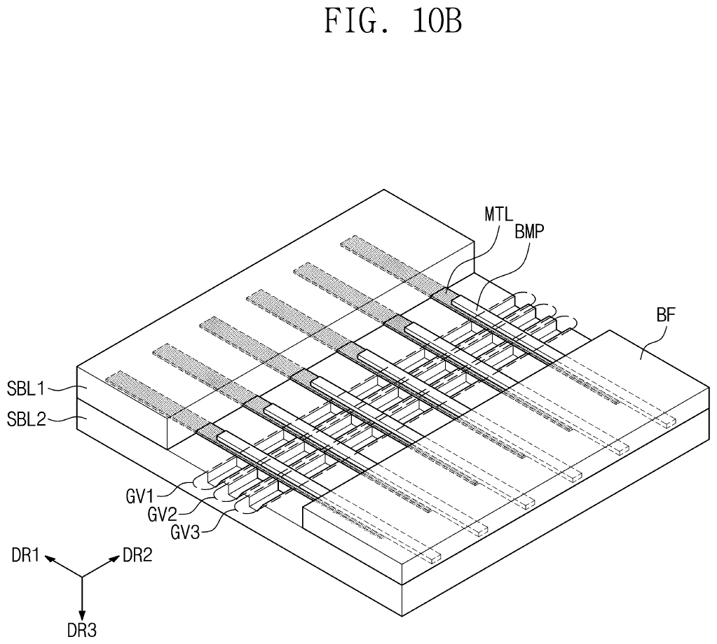

FIGS. 10A and 10B are schematic perspective views illustrating the portion of the display device DD according to an embodiment of the present disclosure. In FIGS. 10A and 10B, for convenience of description, the conductive pattern MP of the display device DD corresponding to FIG. 6 is omitted. In the description of FIGS. 10A to 10B, reference is made to FIGS. 1 to 8, and the explanations of the same reference numerals will be omitted.

Referring to FIG. 10A, two groove groups GV1 and GV2 may be defined in the second sub-base layer SBL2. The groove groups GV1 and GV2 may include a first groove group GV1 and a second groove group GV2, which are spaced apart from each other in the direction parallel to the first direction DR1. The second groove group GV2 may be closer to the base film BF than the first groove group GV1. The second groove group GV2 may be disposed to be spaced apart from the first groove group GV1 in the direction opposite to the first direction DR1.

A plurality of grooves of the first groove group GV1 and the second groove group GV2 may be formed to be spaced apart from each other in the second direction DR2 intersecting the first direction DR1. That is, the grooves of the first groove group GV1 may be formed to be spaced apart from each other in the second direction DR2 intersecting the first direction DR1, and the grooves of the second groove group GV2 may be formed to be spaced apart from each other in the second direction DR2 intersecting the first direction DR1. The grooves of the first groove group GV1 and the second groove group GV2 may be arranged alternately with the bump electrode BMP in the second direction DR2 on a plane.

Referring to FIG. 10B, three groove groups GV1, GV2, and GV3 may be defined in the second sub-base layer SBL2. The plurality of grooves GV1, GV2, and GV3 may include the first groove group GV1, the second groove group GV2, and a third groove group GV3, which are spaced apart from each other in the direction parallel to the first direction DR1. The second groove group GV2 may be closer to the base film BF than the first groove group GV1. The third groove group GV3 may be closer to the base film BF than the second groove group GV2.

The grooves of the first groove group GV1, the second groove group GV2, and the third groove group GV3 may be formed to be spaced apart from each other in the second direction DR2 intersecting the first direction DR1. That is, the grooves of the first groove group GV1 may be formed to be spaced apart from each other in the second direction DR2 intersecting the first direction DR1, the grooves of the second groove group GV2 may be formed to be spaced apart from each other in the second direction DR2 intersecting the first direction DR1, and the grooves of the third groove group GV3 may be formed to be spaced apart from each other in the second direction DR2 intersecting the first direction DR1. The plurality of grooves of the first groove group GV1, the second groove group GV2, and the third groove group GV3 may be arranged alternately with the bump electrode BMP in the second direction DR2 on a plane.

Even when a large amount of conductive material is deposited, the conductive pattern MP in which the conductive material is cured may be formed to be spaced apart from the base film BF as the conductive material is disposed in the grooves of the groove groups GV1, GV2, and GV3.

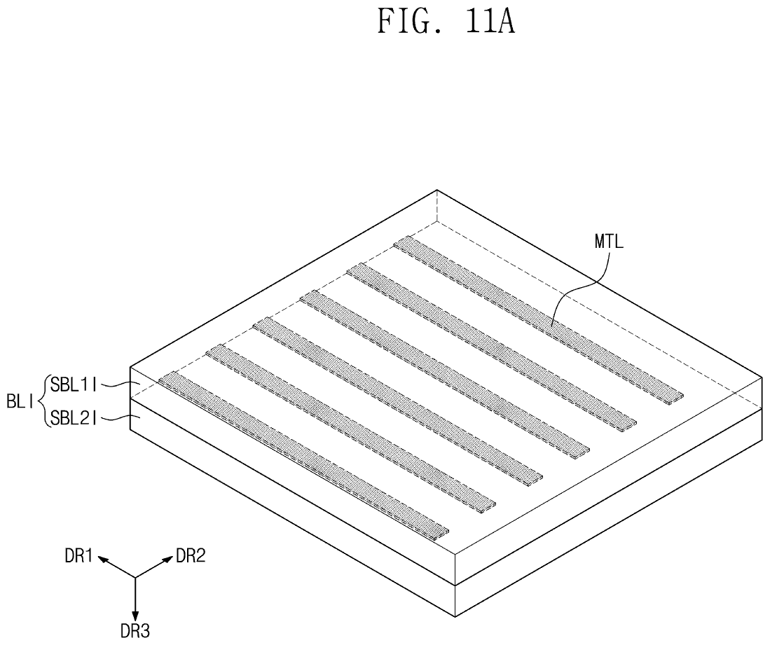

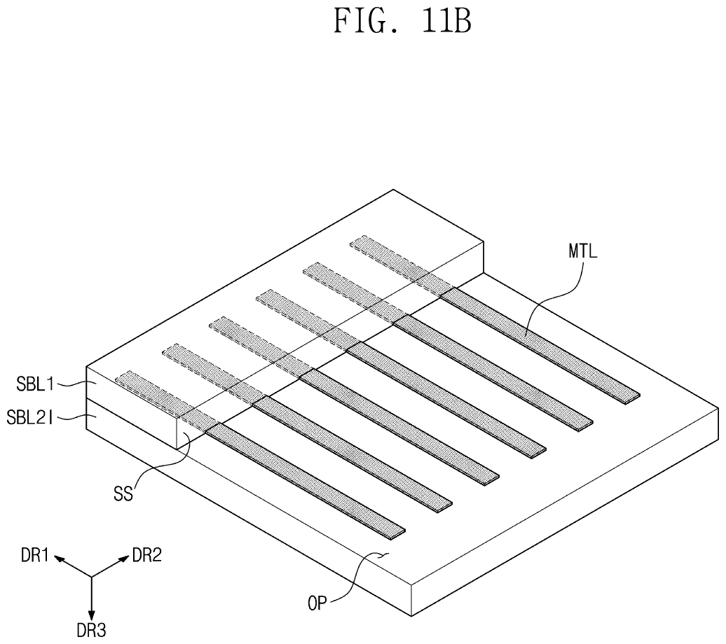

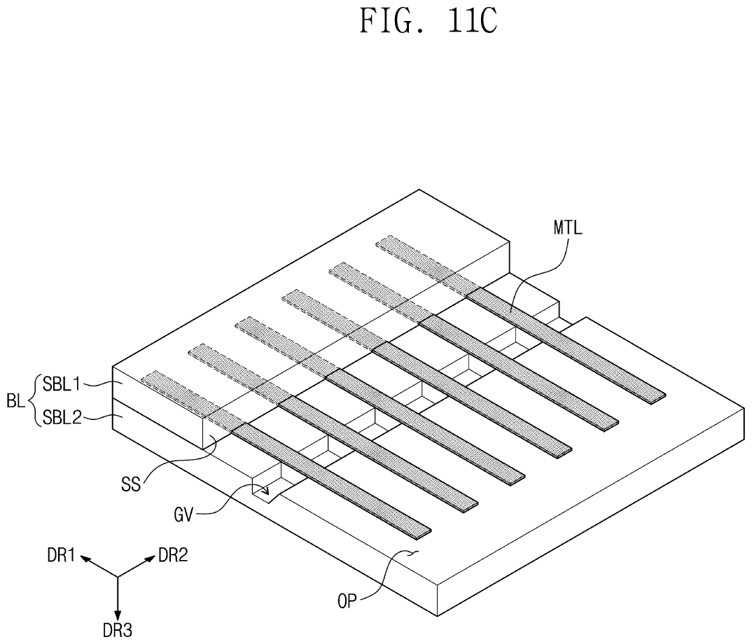

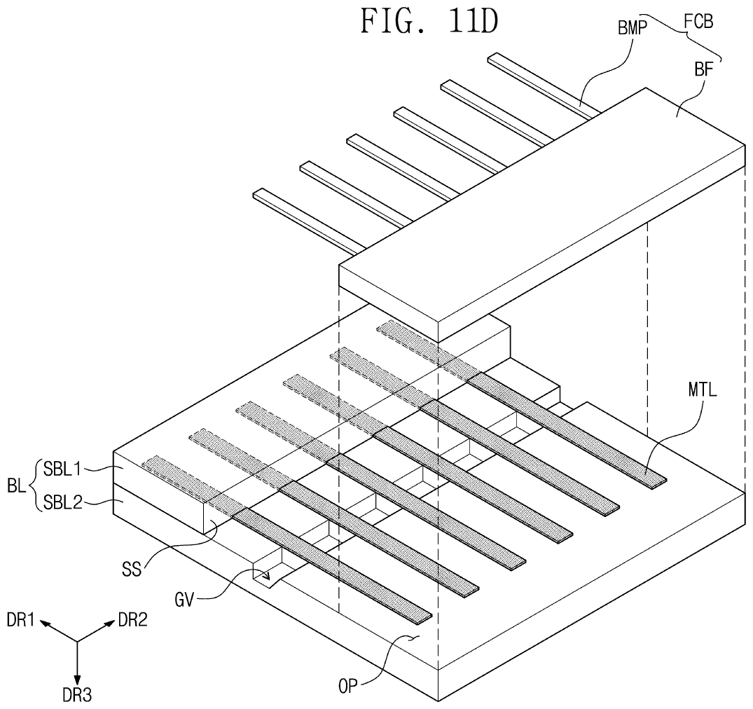

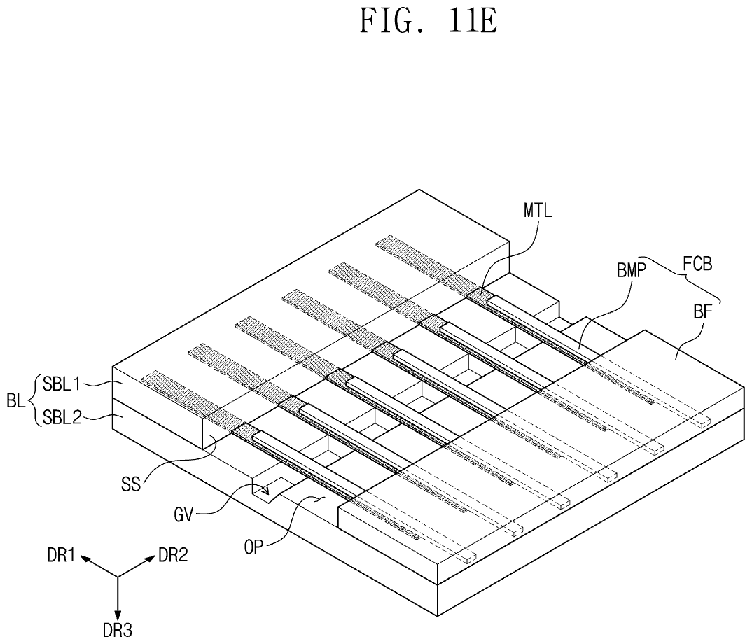

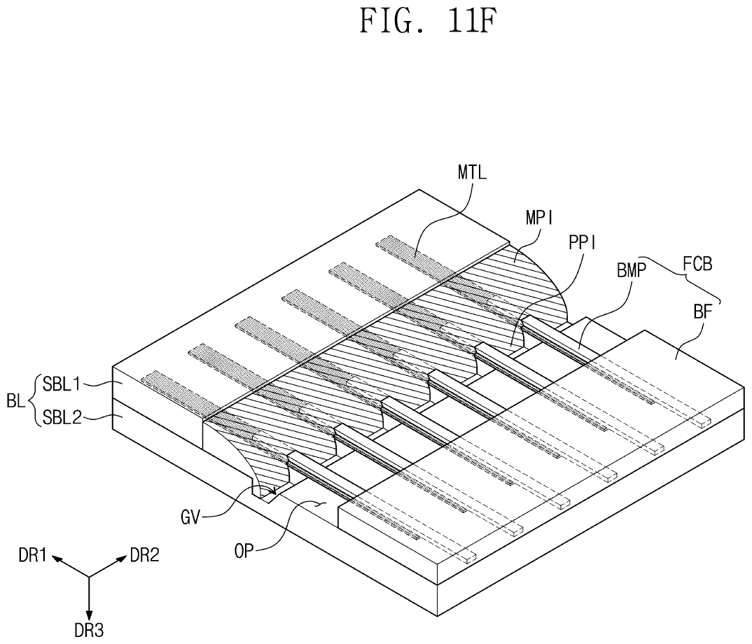

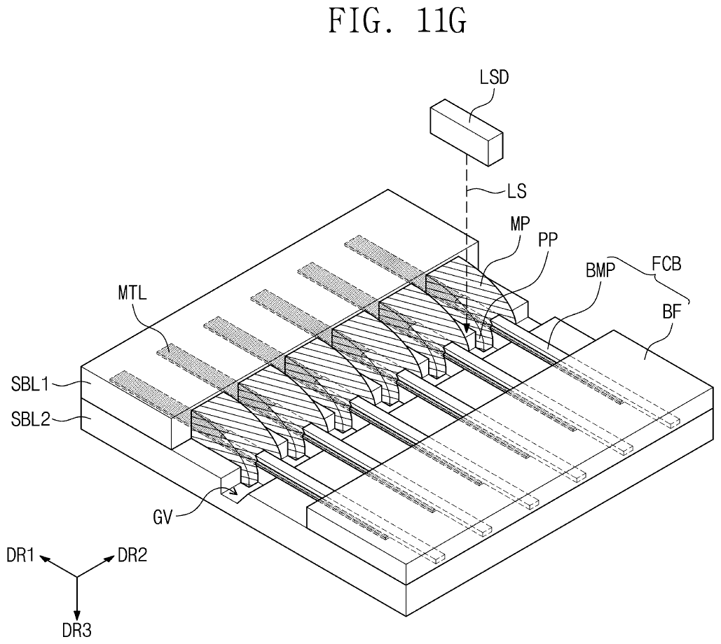

FIGS. 11A to 11G are cross-sectional views illustrating some processes of a method for manufacturing a display device according to an embodiment of the present disclosure. In the description of FIGS. 11A to 11G, the same or similar components described in FIGS. 1 to 8 will be described using the same or similar reference numerals, and thus duplicated descriptions will be omitted.

Referring to FIG. 11A, the method of manufacturing a display device according to the present disclosure may include a process of forming a preliminary base layer BLI and the metal layer MTL. The preliminary base layer BLI may include a first preliminary layer SBL1I and a second preliminary layer SBL2I disposed on a lower surface of the first preliminary layer SBL1I.

The metal layer MTL may be disposed between the first preliminary layer SBL1I and the second preliminary layer SBL2I. That is, the metal layer MTL may be a component embedded in the preliminary base layer BLI. The metal layer MTL may extend in a direction parallel to the first direction DR1.

Thereafter, referring to FIG. 11B, the method of manufacturing a display device according to the present disclosure may include a process of forming the first sub-base layer SBL1 having the base opening OP by etching a portion of the first preliminary layer SBL1I. The base opening OP may be formed by removing the portion of the first preliminary layer SBL1I so that the metal layer MTL is exposed. The portion of the first preliminary layer SBL1I may be removed by directing a laser onto it (e.g., laser irradiation). The first sub-base layer SBL1 may include the one side surface SS defining the base opening OP and the other side surface facing the one side surface SS.

Thereafter, referring to FIG. 11C, the method of manufacturing a display device according to the present disclosure may include a process of forming the second sub-base layer SBL2 having the groove GV by etching the second preliminary layer SBL2I (see FIG. 11B). The groove GV may be formed to be spaced apart from the one side surface SS of the first sub-base layer SBL1 defining the base opening OP in the direction parallel to the first direction DR1.

The process of forming the second sub-base layer SBL2 may include a process of etching the second preliminary layer SBL2I not overlapping the metal layer MTL. A portion of the second preliminary layer SBL2I in a thickness direction may be removed by directing a laser onto it. A partial area removed from the second preliminary layer SBL2I may be defined as the groove GV. The portion of the second preliminary layer SBL2I overlapping the metal layer MTL on a plane is not etched. Thus, the groove GV may be formed at a portion of the second sub-base layer SBL2, which does not overlap the metal layer MTL. In an embodiment, the plurality of grooves GV may be formed by directing a laser toward the second preliminary layer SBL2I. The plurality of grooves GV may be arranged to be spaced apart from each other in the second direction DR2. That is, the plurality of grooves GV may be arranged alternately with the bump electrode BMP in the second direction DR2 on a plane. For example, if a portion of the second preliminary layer SBL2I under the metal layer MTL is not etched, this portion may enable adjacent grooves to be spaced apart from one another.

Referring to FIGS. 10A and 11C, in an embodiment, the process of forming the second sub-base layer SBL2 may include a process of forming the first groove group GV1 including the plurality of grooves GV by etching the second preliminary layer SBL2I and a process of forming the second groove group GV2 including the plurality of grooves GV by etching the second preliminary layer SBL2I. The operation of forming the first groove group GV1 and the process of forming the second groove group GV2 may be substantially the same as the process of forming the plurality of grooves GV as described above. The second groove group GV2 may be formed in an area farther from the first sub-base layer SBL1 than the first groove group GV1.

The first groove group GV1 and the second groove group GV2 may be formed to be spaced apart from each other in the first direction DR1. The first groove group GV1 and the second groove group GV2 may include a plurality of grooves, and the plurality of grooves may be formed to be spaced apart from each other in the second direction DR2 intersecting the first direction DR1. That is, the plurality of grooves of the first groove group GV1 may be formed to be spaced apart from each other in the second direction DR2 intersecting the first direction DR1, and the plurality of grooves of the second groove group GV2 may be formed to be spaced apart from each other in the second direction DR2 intersecting the first direction DR1. The plurality of grooves of the first groove group GV1 and the second groove group GV2 may be arranged alternately with the bump electrode BMP in the second direction DR2 on a plane.

Referring to FIGS. 9A to 9D and 11C, in an embodiment, the process of forming the second sub-base layer SBL2 may include a process of forming the groove GV in a polygonal shape or a semicircular shape in a cross section. The second preliminary layer SBL2I may be etched in various shapes in an etching process so that the groove GV may be formed in a polygonal shape or a semicircular shape.

Thereafter, referring to FIG. 11D, the method of manufacturing a display device according to the present disclosure may include a process of forming the circuit board FCB including the base film BF and the bump electrode BMP disposed in the base film BF and a process of etching a portion of the base film BF so that a portion of the bump electrode BMP is exposed.

The bump electrode BMP of the circuit board FCB may be embedded in the base film BF. A portion of the base film BF may be etched by irradiating it with a laser, thereby exposing a portion of the bump electrode BMP inside the base film BF. Thereafter, a portion of the bump electrode BMP may remain disposed inside the base film BF, and the other portion thereof may be exposed from the base film BF and extend in the first direction DR1.

Thereafter, referring to FIG. 11E, the method of manufacturing a display device according to the present disclosure may include a process of arranging or placing the circuit board FCB so that the bump electrode BMP overlaps a portion of the metal layer MTL exposed by the base opening OP.

The circuit board FCB may be disposed on the second sub-base layer SBL2. The circuit board FCB may be placed so that its bump electrode BMP overlaps the metal layer MTL but does not overlap the groove GV.

Thereafter, referring to FIGS. 11F and 11G, the method of manufacturing a display device according to the present disclosure may include a process of forming the conductive pattern MP in contact with the one side surface SS of the first sub-base layer SBL1 on the bump electrode BMP, the metal layer MTL, and the second sub-base layer SBL2.

The process of forming the conductive pattern MP may include an operation of depositing a conductive material to be in contact with the one side surface SS of the first sub-base layer SBL1 defining the base opening OP. The conductive material may be deposited on the second sub-base layer SBL2. The conductive material may contain silver (Ag). However, the conductive material is not limited to the above example as long as the conductive material is conductive. For example, the conductive material could be copper (Cu). The conductive material may be deposited with a certain thickness while its spread is restricted by the first sub-base layer SBL1.

The process of depositing the conductive material to be in contact with the one side surface SS of the first sub-base layer SBL1 may include an operation of depositing the conductive material to be spaced apart from the base film BF. The conductive material may be deposited to be spaced apart from the base film BF in the first direction DR1.

The process of forming the conductive pattern MP may further include a process of moving a portion of the conductive material into the groove GV or causing the portion to flow into the groove GV. When a large amount of the conductive material is deposited, the conductive material may flow into the groove GV of the second sub-base layer SBL2. That is, even when a large amount of the conductive material is deposited, the conductive material and the base film BF may be spaced apart from each other by the groove GV.

Thereafter, the process of forming the conductive pattern MP may include a process of forming a preliminary conductive pattern MPI by curing the conductive material. As the conductive material hardens during curing, the preliminary conductive pattern MPI may be formed from the hardened conductive material. The curing process may be performed by controlling conditions such as a temperature. The preliminary conductive pattern MPI may be formed on the second sub-base layer SBL2 to extend in the second direction DR2 and to be in contact with one side surface of the first sub-base layer SBL1.

The process of forming the conductive pattern MP may include a process of forming a preliminary protrusion pattern PPI by curing the conductive material.

A large amount of the conductive material may be deposited, and thus the conductive material flowing into the groove GV may also be cured. The conductive material that flows into the groove GV may harden during curing, forming the preliminary protrusion pattern PPI from the hardened conductive material inside the groove GV. The curing process may be performed by controlling conditions such as a temperature. The preliminary protrusion pattern PPI may include the same material as the preliminary conductive pattern MPI and may be formed through the same process.

The plurality of grooves GV are spaced apart from each other in the second direction DR2, the preliminary protrusion patterns PPI are formed inside the grooves GV, and thus the preliminary protrusion patterns PPI may be formed to be spaced apart from each other in the second direction DR2.

Referring to FIG. 11G, the process of forming the conductive pattern MP may include a process of forming the plurality of conductive patterns MP by directing a laser onto the preliminary conductive pattern MPI.

A laser device LSD may emit the laser LS in a direction parallel to the third direction DR3. The preliminary conductive pattern MPI may have an integral shape. That is, the preliminary conductive pattern MPI may have one continuous shape that is not disconnected. The laser device LSD may direct the laser LS onto the preliminary conductive pattern MPI. The laser LS may be directed toward an area that does not overlap the metal layer MTL. When the preliminary conductive pattern MPI is exposed to the laser LS, it may be separated into several patterns. The several separated patterns may form a plurality of conductive patterns MP, and the plurality of conductive patterns MP may be spaced apart from each other in the second direction DR2.

Each of the plurality of conductive patterns MP may be disposed on a corresponding one of the plurality of bump electrodes BMP and a corresponding one of the plurality of metal layers MTL. The plurality of conductive patterns MP may electrically connect the plurality of bump electrodes BMP and the plurality of metal layers MTL. For example, one of the plurality of conductive patterns MP may be disposed on a bump electrode BMP and its corresponding metal layer MTL, establishing an electrical connection between them. The process of forming the conductive pattern MP may include a process of forming the plurality of protrusion patterns PP by directing the laser LS onto the preliminary protrusion pattern PPI.

The laser device LSD may emit the laser LS in the direction parallel to the third direction DR3. The laser device LSD may irradiate the preliminary protrusion pattern PPI with light from the laser LS. The laser LS may be directed toward an area that does not overlap the metal layer MTL. When the preliminary protrusion pattern PPI is exposed to the laser LS, it may be separated into several patterns. The several separated patterns may form a plurality of protrusion patterns PP, and the plurality of protrusion patterns PP may be spaced apart from each other in the second direction DR2. A process of forming the plurality of protrusion patterns PP by directing the laser LS and a process of forming the plurality of conductive patterns MP may be the same process.

Because the protrusion patterns PP and the conductive patterns MP are formed through the same process, the plurality of protrusion patterns PP may be connected to the plurality of conductive patterns MP. One of the plurality of protrusion patterns PP may be connected to a corresponding conductive pattern MP. However, this is merely illustrative, as some or all of the conductive patterns MP remain unconnected to the protrusion patterns PP, depending on the shape of the conductive material as it flows into the groove GV.

According to the above description, as a groove is defined in a second sub-base layer, a conductive pattern may be formed to be spaced apart from a base film. When the conductive pattern is spaced apart from the base film, electrical connection between a plurality of bump electrodes by a plurality of conductive patterns may be prevented.

As the conductive pattern extends in an opposite direction to a first sub-base layer by one side surface of the first sub-base layer, an area in which the bump electrode and the conductive pattern overlap each other may increase. When a contact area between the conductive pattern and the bump electrode increases, a resistance may decrease. Electrical connection reliability between the conductive pattern and the bump electrode may be increased by reducing a resistance between the conductive pattern and the bump electrode.

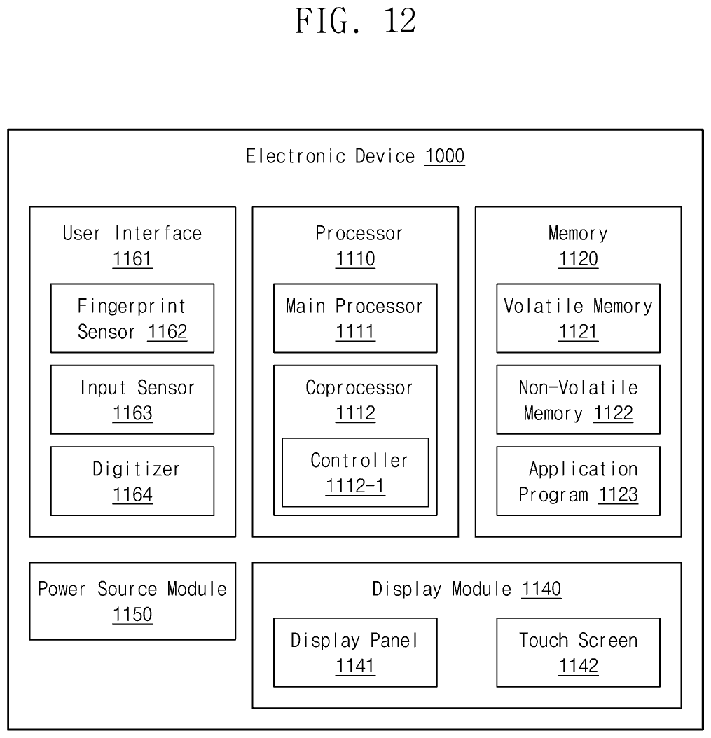

FIG. 12 is a diagram illustrating an electronic device according to an embodiment of the present invention. Referring to FIG. 12, the electronic device 1000 according to one embodiment of the present invention may output various information (e.g., images, text, music, etc.) through a display module 1140, which, for example, may correspond to the display device shown in FIG. 1. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 may be an AR/VR headset.

In some embodiments, memory 1120 may store information such as software codes for operating an application program 1123. The application program 1123 may include software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module or the camera device. The processor 1110 may transmit image data corresponding to a captured image acquired through the camera module to the display module 1140. The display module 1140 may display an image corresponding to the captured image through the display panel 1141.

For example, the camera device may be configured to capture images of an alignment inspection area of the electronic device, where the alignment inspection area includes an alignment bump (e.g., ABP), an alignment pad (e.g., APD) bonded to the alignment bump, and an alignment polymer pattern (e.g., APP) that is spaced apart from the alignment pad; and the processor 1110 may be configured to: process the captured images to detect center positions of the alignment bump, the alignment pad, and the alignment polymer pattern; compare the detected center positions of the alignment bump and the alignment pad with the center position of the alignment polymer pattern; and determine presence of misalignment based on results of the compare.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

The memory 1120 may store instructions, that, when executed by the processor 1110, cause it to perform the above steps of processing, comparing, and determining misalignment.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data.

The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The processor 1110 may provide an output signal to the user interface 1161 based on the determination of misalignment, where the output signal can be used to alert operators or activate further inspection or correction processes.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device shown in FIG. 1.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display unit shown in FIG. 1.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

Although the description has been made above with reference to certain embodiments, it should be understood that those skilled in the art or those having ordinary knowledge in the art may variously modify and change the present disclosure without departing from the spirit and technical scope of the present disclosure described in the appended claims. Thus, the technical scope of the present disclosure is not limited to the detailed description of the specification.

What is claimed is:

1. A display device comprising:
a base layer including a first sub-base layer with a base opening, a first barrier layer disposed on the first sub-base layer, a second barrier layer disposed on the first barrier layer, and a second sub-base layer disposed on the second barrier layer;
a metal layer disposed between the first barrier layer and the second barrier layer with a portion of the metal layer exposed through the base opening;
a base film disposed inside the base opening;
a bump electrode including a first portion disposed inside the base film and a second portion that extends from the base film in a first direction; and
a conductive pattern disposed on the bump electrode and the metal layer,
wherein the conductive pattern is in contact with one side surface of the first sub-base layer defining the base opening.

2. The display device of claim 1, wherein the conductive pattern is spaced apart from the base film in the first direction.

3. The display device of claim 1, wherein the conductive pattern is a plurality of conductive patterns, and
wherein the plurality of conductive patterns are spaced apart from each other in a second direction intersecting the first direction.

4. The display device of claim 1, wherein a groove is defined in the second barrier layer and the second sub-base layer.

5. The display device of claim 4, wherein a portion of the conductive pattern is disposed inside the groove.

6. The display device of claim 4, wherein the groove has a semicircular shape in a cross section.

7. The display device of claim 4, wherein the second sub-base layer includes a first inner surface defining the groove and a second inner surface connected to the first inner surface.

8. The display device of claim 4, wherein the second sub-base layer includes a first inner surface defining the groove, a second inner surface connected to the first inner surface, and a third inner surface connected to the second inner surface.

9. The display device of claim 4, wherein the groove is a plurality of grooves, and
wherein the plurality of grooves are spaced apart from each other in a second direction intersecting the first direction.

10. The display device of claim 4, wherein the groove is a plurality of grooves, the bump electrode is a plurality of bump electrodes, and
wherein the plurality of grooves are arranged alternately with the plurality of bump electrodes in a second direction intersecting the first direction.

11. The display device of claim 4, wherein the groove is a plurality of grooves, and
wherein the plurality of grooves do not overlap the bump electrode.

12. The display device of claim 4, wherein the groove is a plurality of grooves, and
wherein the plurality of grooves include a first groove group and a second groove group spaced apart from each other in the first direction, and the second groove group is positioned closer to the base film than the first groove group.

13. A method of manufacturing a display device, the method comprising:
forming a preliminary base layer including a first preliminary layer and a second preliminary layer disposed on a lower surface of the first preliminary layer, and a metal layer disposed between the first preliminary layer and the second preliminary layer;
etching a portion of the first preliminary layer to form a first sub-base layer having a base opening;
etching the second preliminary layer to form a second sub-base layer having a groove;
providing a circuit board including a base film and a bump electrode disposed inside the base film;
etching a portion of the base film so that a portion of the bump electrode is exposed;
positioning the circuit board on the second sub-base layer so that the bump electrode and the metal layer exposed by the base opening overlap each other; and
forming a conductive pattern in contact with one side surface of the first sub-base layer on the bump electrode, the metal layer, and the second sub-base layer.

14. The method of claim 13, wherein the forming of the conductive pattern in contact with the one side surface of the first sub-base layer on the bump electrode, the metal layer, and the second sub-base layer comprises:
depositing a conductive material to be in contact with the one side surface of the first sub-base layer defining the base opening;
forming a preliminary conductive pattern by curing the conductive material; and
forming a plurality of conductive patterns by irradiating the preliminary conductive pattern with a laser.

15. The method of claim 14, wherein the depositing of the conductive material to be in contact with the one side surface of the first sub-base layer defining the base opening comprises:
depositing the conductive material to be spaced apart from the base film.

16. The method of claim 14, wherein the forming of the conductive pattern in contact with the one side surface of the first sub-base layer on the bump electrode, the metal layer, and the second sub-base layer comprises:
moving a portion of the conductive material into the groove;
forming a preliminary protrusion pattern by curing the conductive material; and
forming a plurality of protrusion patterns by irradiating the preliminary protrusion pattern with the laser, and
wherein the plurality of protrusion patterns are connected to the plurality of conductive patterns.

17. The method of claim 13, wherein the forming of the second sub-base layer having the groove by etching the second preliminary layer comprises:
etching a portion of the second preliminary layer not overlapping the metal layer.

18. The method of claim 13, wherein the forming of the second sub-base layer having the groove by etching the second preliminary layer comprises:
etching the second preliminary layer to form a plurality of grooves alternately arranged with a plurality of metal patterns of the metal layer on a plane.

19. The method of claim 13, wherein the forming of the second sub-base layer having the groove by etching the second preliminary layer comprises:
forming a first groove group including a plurality of grooves by etching the second preliminary layer; and
forming a second groove group including a plurality of grooves by etching the second preliminary layer in an area farther from the first sub-base layer than the first group groove, and
wherein the first groove group and the second groove group are spaced apart from each other in a first direction, and the plurality of grooves of the first groove group and the second groove group include grooves spaced apart from each other in a second direction intersecting the first direction.

20. An electronic device comprising:
a display device comprising:
a base layer comprising a first sub-base layer disposed on a second sub-base layer, the first sub-base layer having a base opening;
a metal layer disposed between the first sub-base layer and the second sub-base layer, with a portion of the metal layer exposed through the base opening;
a base film disposed inside the base opening;
a bump electrode including a first portion disposed inside the base film and a second portion extending from the base film in a first direction; and
a conductive pattern disposed on the bump electrode and the metal layer, wherein the conductive pattern is in contact with one side surface of the first sub-base layer defining the base opening; and
a control circuit configured to supply electrical signals to the bump electrode for operating the display device.
